(19) United States
(12) Patent Application Publication
(10) Pub. No.: US 2024/0175126 A1
(43) Pub. Date: May 30, 2024

(54) GAS RECYCLING SYSTEMS, SUBSTRATE PROCESSING SYSTEMS, AND RELATED APPARATUS AND METHODS FOR SEMICONDUCTOR MANUFACTURING

(71) Applicant: Applied Materials, Inc., Santa Clara, CA (US)

(72) Inventors: Mukhles SOWWAN, Sunnyvale, CA (US); Shu-Kwan LAU, Sunnyvale, CA (US)

(21) Appl. No.: 18/070,010

(22) Filed: Nov. 28, 2022

(51) Int. Cl. C23C 16/44; B01D 53/18; B01D 53/32; C30B 25/14

(52) U.S. Cl. CPC C23C 16/4412; B01D 53/18; B01D 53/326; C23C 16/4408; C30B 25/14

(57) ABSTRACT

The present disclosure generally relates to gas recycling systems, substrate processing systems, and related apparatus and methods for semiconductor manufacturing. In one or more implementations, unreacted gases from chambers can be used, recycled, and used one or more additional times. In one implementation, a gas recycling system includes a pump configured to fluidly connect to one or more outlet passages of a processing chamber to exhaust a gas from the processing chamber. The system includes one or more filtration devices in fluid communication with the pump such that the gas flows from the pump to the one or more filtration devices. The one or more filtration devices are configured to remove one or more impurities from the gas. The system includes a gas supply system in fluid communication with the one or more filtration devices such that the filtered gas flows to the gas supply system.

### BACKGROUND

### Field

Embodiments of the present disclosure generally relate to gas recycling systems, substrate processing systems, and related apparatus and methods for semiconductor manufacturing. In one or more implementations, unreacted gases from chambers can be used, recycled, and used one or more additional times.

### Description of the Related Art

Semiconductor substrates are processed for a wide variety of applications, including the fabrication of integrated devices and microdevices. During processing (such as epitaxial deposition processing), reactant gases are used to deposit material on substrates and/or to clean chamber components. Inert gases can also be used and certain reactive gases may not completely react during processing or cleaning.

Hence, many gases are wasted in semiconductor manufacturing, which involves increased emissions and carbon footprint, increased gas consumption and energy consumption, and increased operating costs (such as materials costs, delivery costs, and power costs). Such hindrances can be exacerbated by other factors, such as supply chain shortages.

Therefore, a need exists for improved systems, apparatus, and methods that facilitate reduced waste of gases.

### SUMMARY

The present disclosure generally relates to gas recycling systems, substrate processing systems, and related apparatus and methods for semiconductor manufacturing. In one or more implementations, unreacted gases from chambers can be used, recycled, and used one or more additional times.

In one implementation, a gas recycling system for connection to a processing chamber includes a pump configured to fluidly connect to one or more outlet passages of the processing chamber to exhaust a gas from the processing chamber. The system includes one or more filtration devices in fluid communication with the pump such that the gas flows from the pump to the one or more filtration devices. The one or more filtration devices are configured to remove one or more impurities from the gas to generate a filtered gas that has a purity content of 99.9% or higher. The system further includes a gas supply system in fluid communication with the one or more filtration devices such that the filtered gas flows from the one or more filtration devices to the gas supply system. The gas supply system is configured to fluidly connect to one or more inlet passages of the processing chamber.

In one implementation, a system for substrate processing includes a processing chamber which includes a chamber body at least partially defining an internal volume. The processing chamber includes a plurality of inlet passages, one or more outlet passages, a substrate support disposed in the internal volume, and one or more heat sources configured to heat the internal volume. The system includes a gas supply system in fluid communication with the plurality of inlet passages to supply a gas to the internal volume of the processing chamber, and a gas recycling system in fluid communication between the one or more outlet passages and the gas supply system. The gas recycling system includes a pump in fluid communication with the one or more outlet passages to remove the gas from the internal volume of the processing chamber. The gas recycling system includes one or more filtration devices in fluid communication between the pump and the gas supply system such that the gas flows from the pump to the one or more filtration devices. The one or more filtration devices are configured to remove one or more impurities from the gas to generate a filtered gas that has a purity content of 99.9% or higher. The one or more filtration devices are in fluid communication with the gas supply system such that the filtered gas flows from the one or more filtration devices to the gas supply system.

In one implementation, a method of recycling gas in relation to semiconductor manufacturing includes pumping a gas out of an internal volume of a processing chamber. The method includes filtering the gas using a first filtration operation, filtering the gas using a second filtration operation to generate a filtered gas that has a purity content of 99.9% or higher, and flowing the filtered gas to a gas supply system. The method includes reintroducing the filtered gas to the processing chamber using the gas supply system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional view of a system for substrate processing, according to one implementation.

FIG. 2 is a schematic partial view of a purge supply system of the gas supply system, according to one implementation.

FIG. 3 is a schematic partial view of a cleaning supply system, according to one implementation.

FIG. 4 is a schematic partial view of a process supply system, according to one implementation.

FIG. 5 is a schematic block diagram view of a method of recycling gas in relation to semiconductor manufacturing, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to gas recycling systems, substrate processing systems, and related apparatus and methods for semiconductor manufacturing. In one or more implementations, unreacted gases from chambers can be used, recycled, and used one or more additional times.

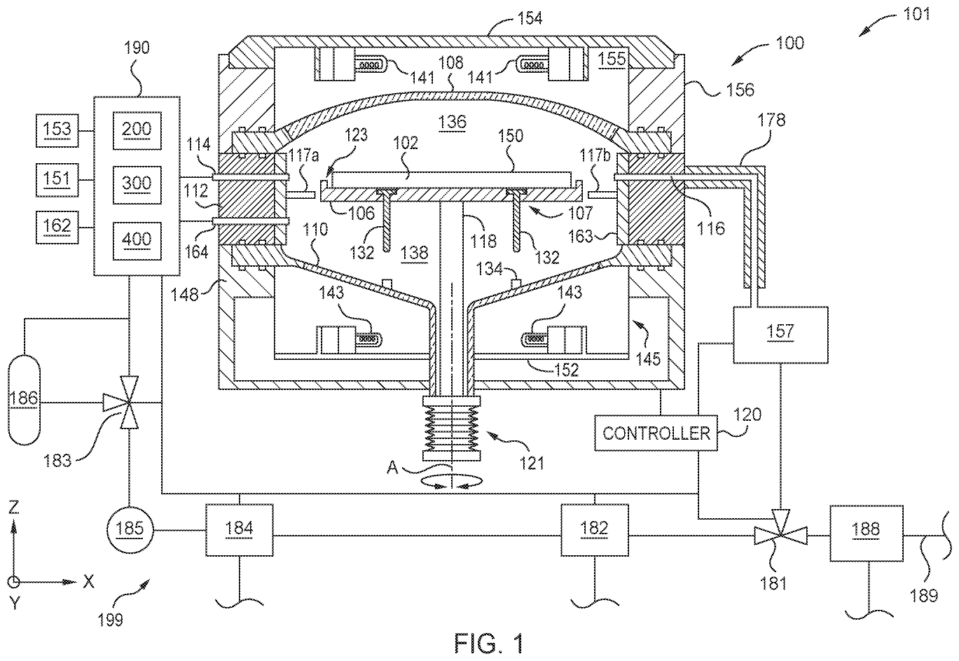

FIG. 1 is a schematic cross-sectional view of a system 101 for substrate processing, according to one implementation. The system 101 includes a processing chamber 100. In one or more embodiments, the processing chamber 100 is a deposition chamber. In one embodiment, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102 to deposit film.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heating module 155. The lid 154 may include a plurality of sensors (not shown) disposed therein or thereon for measuring temperature(s) within the processing chamber 100. The plurality of lower heat sources 143 are disposed between the lower window 110 and a floor 152. The plurality of lower heat sources 143 form a portion of a lower heating module 145. The upper window 108 is an upper dome and is formed of an energy transmissive material, such as quartz. The lower window 110 is a lower dome and is formed of an energy transmissive material, such as quartz.

In the implementation shown in FIG. 1, the heat sources 141, 143 are lamps. Other heat sources are contemplated, such as resistive heaters, light emitting diodes (LEDs), and/or lasers.

A process volume 136 and a purge volume 138 are formed between the upper window 108 and the lower window 110. The process volume 136 and the purge volume 138 are part of an internal volume defined at least partially by the upper window 108, the lower window 110, and the one or more liners 163.

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are sized to accommodate a lift pin 132 for lowering and/or lifting of the substrate 102 from the substrate support 106 before and/or after a deposition process is performed. The lift pins 132 may rest on lift pin stops 134 when the substrate support 106 is lowered from a process position to a transfer position.

The flow module 112 includes a plurality of inlet passages that include a plurality of process inlet passages 114 and a plurality of purge inlet passages 164. The flow module 112 includes one or more outlet passages that include one or more outlet passages 116. The plurality of process inlet passages 114 and the plurality of purge inlet passages 164 are disposed on the opposite side of the flow module 112 from the one or more outlet passages 116. One or more flow guides 117a, 117b are disposed below the plurality of process inlet passages 114 and the one or more outlet passages 116. The one or more flow guides 117a, 117b are disposed above the purge inlet passages 164. In one or more embodiments, the one or more flow guides 117a, 117b include a pre-heat ring. One or more liners 163 are disposed on an inner surface of the flow module 112 and protect the flow module 112 from reactive gases used during deposition operations and/or cleaning operations. The process inlet passages 114 and the purge inlet passages 164 are each positioned to flow a gas parallel to the top surface 150 of a substrate 102 disposed within the process volume 136. The process inlet passages 114 and the purge inlet passages 164 are fluidly connected to a gas supply system 190 which coordinates the gases to be delivered to the processing chamber 100. One or more process gas sources 151, one or more cleaning gas sources 153, and one or more purge gas sources 162 are fluidly connected to the gas supply system 190. In one or more embodiments, the one or more process gas sources 151 include one or more reactive gas sources and one or more carrier gas sources.

A gas recycling system 199 is fluidly connected to the gas supply system 190 to provide recycled gas to the gas supply system 190 for re-use in the processing chamber 100. The one or more outlet passages 116 are fluidly connected to an exhaust pump 157 (e.g., a vacuum pump). The exhaust pump 157 is fluidly connected to the gas recycling system 199 to pump gas from the processing chamber 100 to a first flow divider 181 of the gas recycling system 199. The first flow divider 181 is in fluid communication with the exhaust pump 157.

The first flow divider 181 is fluidly connected to a first filtration device 182. The first filtration device 182 is fluidly connected to a second filtration device 184. The first flow divider 181 is fluidly connected to a third filtration device 188. Using the first flow divider 181, at least a portion of gas exhausted from the processing chamber 100 can be directed to a first filtration device 182 to be recycled back into the processing chamber 100 through the gas supply system 190. Using the first flow divider 181, at least a portion of the gas exhausted from the processing chamber 100 can be directed to the third filtration device 188 along a bypass line 189 that bypasses the first and second filtration devices 182, 184.

At least a portion of the gas can be directed to the bypass line 189 if such gas is unfit to be recycled. At least a portion of the gas can be directed to the bypass line 189 to be recycled using an additional recycling system (and then recycled to the gas supply system 190) if the composition is different than a composition used along the gas recycling system 199. In one or more embodiments, at least a portion of the gas directed to the bypass line 189 is stored, flared, and/or recycled to the gas supply system 190 in a manner that is fluidly separate from the first and second filtration devices 182, 184.

Gas to be recycled along the gas recycling system 199 flows from the first filtration device 182 to the second filtration device 184. Each of the filtration devices 182, 184, 188 can include a scrubber, an electrochemical filter, a porous ceramic adsorbent-based system, a pressure swing adsorption-based system, a Pd adsorption/release film-based system, and/or another type of filtration device. The present disclosure contemplates that one or more of the first filtration device 182, the second filtration device 184, and/or the third filtration device 188 can be the same as each other or different from each other. In one or more embodiments, the first and third filtration devices 182, 188 each includes a scrubber, and the second filtration device 184 includes an electrochemical filter.

The scrubber used can include a pollution control device that uses a liquid (such as water) to remove particulate matter or gases from the gas exhausted from the processing chamber 100. The gas enters the scrubbed at or adjacent to a center of the scrubber, where the liquid rains down from above in the scrubber. The liquid traps the contaminants which sink to the bottom while the exhausted escapes out through a top of the scrubber. The electrochemical filter can be a hydrogen recovery system. The electrochemical filter can be an anode, electrolyte, and cathode device where hydrogen ions are pulled in to the electrolyte by the anode and combine to form hydrogen gas (H₂) in the cathode.

In one or more embodiments, the first filtration device 182 and the second filtration device 184 filter the gas (exhausted from the processing chamber 100) to generate a filtered gas that has a purity content of 95% or higher. The purity content is a concentration of an element (such as hydrogen (H₂)) by atomic percentage. In one or more embodiments, the first filtration device 182 removes contaminants (e.g., pollutants) from the gas, and the second filtration device 184 separates one element (e.g., hydrogen) from other elements (such as nitrogen and/or other gas(es)). In one or more embodiments, the purity content is 99% or higher, such as 99.9% or higher. In one or more embodiments, the purity content is at least a 5N level such that the purity content is 99.999% or higher. The gas recycling system 199 includes one or more filtration devices 182, 184. In one or more embodiments, a single filtration device can be used in the gas recycling system 199. In one or more embodiments, more than two filtration devices 182, 184 can be used in the gas recycling system 199.

After flowing through the second filtration device 184, the filtered gas is compressed by a compressor 185 in fluid communication with the first and second filtration devices 182, 184. A second flow divider 183 is fluidly connected to the compressor 185. In one or more embodiments, each of the first flow divider 181 and/or the second flow divider 183 includes a valve, for example a directional valve (such as a three way valve).

A buffer tank 186 is fluidly connected to the compressor 185 through the second flow divider 183. In one or more embodiments, at least a portion of the filtered gas is stored (at least temporarily, e.g. for later use) in the buffer tank 186 before being supplied to the gas supply system 190. The buffer tank 186 can facilitate pressurizing the filtered gas. In one or more embodiments, at least a portion of the filtered gas flows directly from the compressor 185 and to the gas supply system 190 for injection (again) into the processing chamber 100.

Using the compressor 185 and/or the buffer tank 186, the filtered gas is pressurized to a threshold pressure. In one or more embodiments, the threshold pressure is equal to or larger than an operational pressure for the filtered gas used in the processing chamber 100. In one or more embodiments, the operational pressure is a processing pressure (e.g., 600 Torr or higher, such as within a range of 750 Torr to 770 Torr), used during a deposition operation in the processing chamber 100. In one or more embodiments, the operational pressure is a cleaning pressure used during a cleaning operation in the processing chamber 100, and/or a purge pressure used during a purge operation in the processing chamber 100. In one or more embodiments, the threshold pressure is equal to or larger than a storage pressure (e.g., for the buffer tank 186). In one or more examples, the storage pressure is within a range of 0 bar to 10 bar. In one or more embodiments, the threshold pressure is 15 psig or higher, such as 75 psig or higher (for example 100 psig or higher).

The filtered gas generated using the gas recycling system 199 can be re-used as a process gas, a cleaning gas, and/or a purge gas. In one or more embodiments, the filtered gas includes hydrogen (H₂) and has the purity content of hydrogen by atomic percentage. Other material(s) are contemplated for the filtered gas.

One or more process gases supplied to the gas supply system 190 using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of hydrogen (H₂), argon (Ar), helium (He), and/or nitrogen (N₂)). One or more cleaning gases supplied using the one or more cleaning gas sources 153 can include one or more of hydrogen (H₂) and/or chlorine (Cl). In one embodiment, which can be combined with other embodiments, the one or more process gases include silicon phosphide (SiP) and/or phosphine (PH₃), and the one or more cleaning gases include hydrochloric acid (HCl). The present disclosure contemplates that the carrier gas(es), purge gas(es), and/or cleaning gas(es) are all candidates for recycling described herein.

The one or more outlet passages 116 are further connected to or include an exhaust system 178. The exhaust system 178 fluidly connects the one or more outlet passages 116 to the exhaust pump 157. The exhaust system 178 can assist in the controlled deposition of a layer on the substrate 102. The exhaust system 178 is disposed on an opposite side of the processing chamber 100 relative to the inlet passages 114, 164.

As shown, the system 101 includes a controller 120 is in communication with the processing chamber 100 and is used to control processes and methods, such as the operations of the methods described herein. The controller 120 is in communication with the gas recycling system 199 (such as the exhaust pump 157, the first flow divider 181, the second flow divider 183, the first filtration device 182, the second filtration device 184, and/or the third filtration device 188), and the gas supply system 190. The controller 120 controls the first flow divider 181 and second flow divider 183 and monitors the purity content of the filtered gas (generated using the gas recycling system 199) and/or the exhausted gas (exhausted from the processing chamber 100) using sensors disposed along the exhaust pump 157, the first filtration device 182, the second filtration device 184, the third filtration device 188, the gas supply system 190, and/or the buffer tank 186. By monitoring the purity content of the gas, the controller 120 can control the flow dividers 181, 183 and the gas supply system 190 and determine (and control) where gas(es) flow in the system 101.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (the pressure of a recycled gas, the purity of a recycled gas, the chemical makeup of a recycled gas) and operations are stored in the memory as a software routine that is executed or invoked to turn the controller 120 into a specific purpose controller to control the operations of the various systems/chambers/recycling systems/modules described herein. The controller 120 is configured to conduct any of the operations described herein. The instructions stored on the memory, when executed, cause one or more of operations of method 500 (described below) to be conducted.

The various operations described herein can be conducted automatically using the controller 120, or can be conducted automatically and/or manually with certain operations conducted by a user.

The controller 120 is configured to adjust output to controls of the system 101 based off of sensor readings, a system model, and stored readings and calculations. The controller 120 includes embedded software and a compensation algorithm to calibrate measurements. The controller 120 can include one or more machine learning algorithms and/or artificial intelligence algorithms that estimate optimized parameters for deposition operation(s), purge operation(s), and/or cleaning operation(s). The one or more machine learning algorithms and/or artificial intelligence algorithms can use, for example, a regression model (such as a linear regression model) or a clustering technique to estimate optimized parameters. The algorithm can be unsupervised or supervised.

The one or more machine learning algorithms and/or artificial intelligence algorithms can optimize parameters used in relation to recycling operations. The optimized parameters can include, for example, purity content, time in the buffer tank 186, flow rate through the first and second filtration devices 182, 184, flow rate through the third filtration device 188, and/or the threshold pressure.

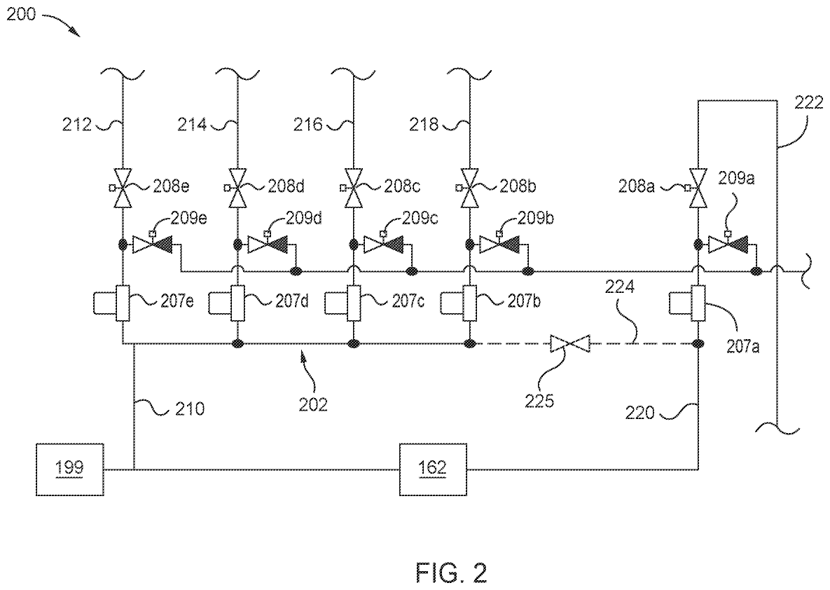

In one or more embodiments, the gas supply system 190 is responsible for providing all gases to the processing chamber 100 whether the gases come from a gas source 151, 153, 162 or the gas recycling system 199. The gas supply system 190 is controlled by the controller 120. Three internal systems of the gas supply system are visualized in FIGS. 2, 3, and 4, as described below.

FIG. 2 is a schematic partial view of a purge supply system 200 of the gas supply system 190, according to one implementation. The purge supply system 200 is part of the gas supply system 190.

Gas is shown being supplied to and distributed from the purge supply system 200. The purge supply system 200 supplies one or more purge gases to the processing chamber 100. The purge supply system 200 includes one or more mass flow controllers (MFCs) 207a-207e and one or more purge header lines 202 in fluid communication with the one or more purge gas sources 162 through a first inlet line 220 and a second inlet line 210.

The one or more purge gas sources 162 supply one or more purge gases to the one or more purge header lines 202 as primary purge gas(es). The one or more purge header lines 202 are fluidly connected to the gas recycling system 199. The filtered gas flows from the gas recycling system 199 and into the one or more purge header lines 202 on an upstream side of the one or more MFCs 207-207e as a supplemental purge gas. In one or more embodiments, the one or more purge gas sources 162 supply nitrogen (N₂) and hydrogen (H₂) to the first inlet line 220 as primary purge gases. In one or more embodiments, the one or more purge gas sources 162 supply nitrogen (N₂) to the second inlet line 210 as a primary purge gas, and the gas recycling system 199 supplies the filtered gas (having the purity content of hydrogen (H₂)) to the second inlet line 210 as a supplemental purge gas.

The purge supply system 200 includes a plurality of outlet lines 212, 214, 216, 218, 222 that are fluidly connected to various inlet passages of the processing chamber 100. In one or more embodiments, a first outlet line 222 supplies purge gas(es) to the process inlet passages 114, and a second outlet line 212 supplies purge gas(es) to the motion assembly 121 (such as within a bellows of the motion assembly. In one or more embodiments, a third outlet line 214 supplies purge gas(es) to the purge inlet passages 164 to purge the purge volume 138, and a fourth outlet line 216 supplies purge gas(es) to a transfer opening of the processing chamber 100 (such as a slit valve). In one or more embodiments, a fifth outlet line 218 supplies purge gas(es) to an upper volume of the processing chamber 100 (such as to purge the process volume 136 and/or the upper window 108).

The present disclosure contemplates that the first inlet line 220 can be fluidly isolated from the second inlet line 210. In one or more embodiments, a connecting line 224 can fluidly connect the first and second inlet lines 220, 210. An isolation device 225 (such as an isolation valve, for example a two-way valve), can selectively isolate and allow fluid to flow from one inlet line 210, 220 to the other inlet line 210, 220. The connecting line 224 can control mixing of the filtered gas and the gas(es) supplied from the one or more purge gas sources 162. For example, if the purge gas supplied through the outlet lines 212, 214, 216, 218 is to be 75% filtered gas (e.g., recycled gas) and 25% gas supplied from the one or more purge gas sources 162, then the isolation device 225 can be opened an amount to let into outlet lines 212, 214, 216, 218 gas from the first inlet line 220. The present disclosure contemplates that the connecting line 224 and the isolation device 225 can be omitted. In one or more embodiments, the filtered gas is supplied to the second through fifth outlet lines 212, 214, 216, 218 but is not supplied to the first outlet line 222.

An MFC 207a-207e, a supply valve 208a-208e, and a bypass valve 209a-209e can correspond to each outlet line 212, 214, 216, 218, 222.

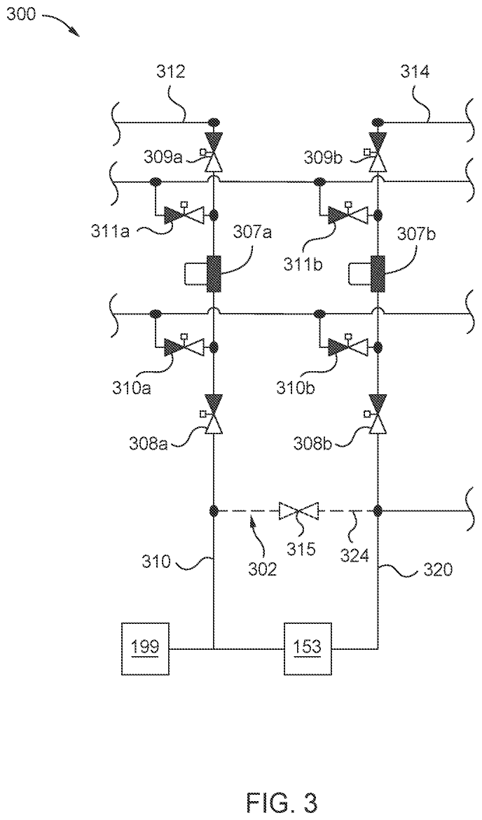

FIG. 3 is a schematic partial view of a cleaning supply system 300, according to one implementation. The cleaning supply system 300 is part of the gas supply system 190.

The cleaning supply system 300 supplies one or more cleaning gases to the processing chamber 100. The cleaning supply system 300 includes one or more MFCs 307a, 307b and one or more cleaning header lines 302 in fluid communication with the one or more cleaning gas sources 153 through a first inlet line 310 and a second inlet line 320.

The one or more cleaning gas sources 153 supply one or more cleaning gases to the one or more cleaning header lines 302 as primary cleaning gas(es). The one or more cleaning header lines 302 is fluidly connected to the gas recycling system 199. The filtered gas flows from the gas recycling system 199 and into the one or more cleaning header lines 302 on an upstream side of the one or more MFCs 307a, 307b as a supplemental cleaning gas. In one or more embodiments, the one or more cleaning gas sources 153 supply chlorine (Cl) to the first inlet line 310 as a primary cleaning gas, and the gas recycling system 199 supplies the filtered gas (having the purity content of hydrogen (H₂)) to the first inlet line 310 as a supplemental cleaning gas. In one or more embodiments, the one or more cleaning gas sources 153 supply hydrogen (H₂) and chlorine (Cl) to the second inlet line 320 as primary cleaning gases.

The cleaning supply system 300 includes a plurality of outlet lines 312, 314 that are fluidly connected to various inlet passages of the processing chamber 100. In one or more embodiments, a first outlet line 312 supplies cleaning gas(es) having a first flow rate that is higher than a second flow rate of cleaning gas(es) supplied using a second outlet line 314.

The present disclosure contemplates that the first inlet line 310 can be fluidly isolated from the second inlet line 320, and the first outlet line 312 can be fluidly isolated from the second outlet line 314. An isolation device 315 (such as an isolation valve, for example a two-way valve), can selectively isolate and allow fluid to flow from one inlet line 310, 320 to the other inlet line 310, 320. A connecting line 324 can control mixing of the filtered gas and the gas(es) supplied from the one or more cleaning gas sources 153. The present disclosure contemplates that the connecting line 324 and the isolation device 315 can be omitted. In one or more embodiments, the filtered gas is supplied to the first outlet line 312 (having the higher flow rate) but is not supplied to the second outlet line 320 (having the lower flow rate). In one or more embodiments, the isolation device 315 can be opened to supply more hydrogen into the first outlet line 312, in addition to the filtered gas.

An MFC 307a, 307b, two supply valves 308a, 308b, 309a, 309b, and two bypass valves 310a, 310b, 311a, 311b can correspond to each outlet line 312, 314.

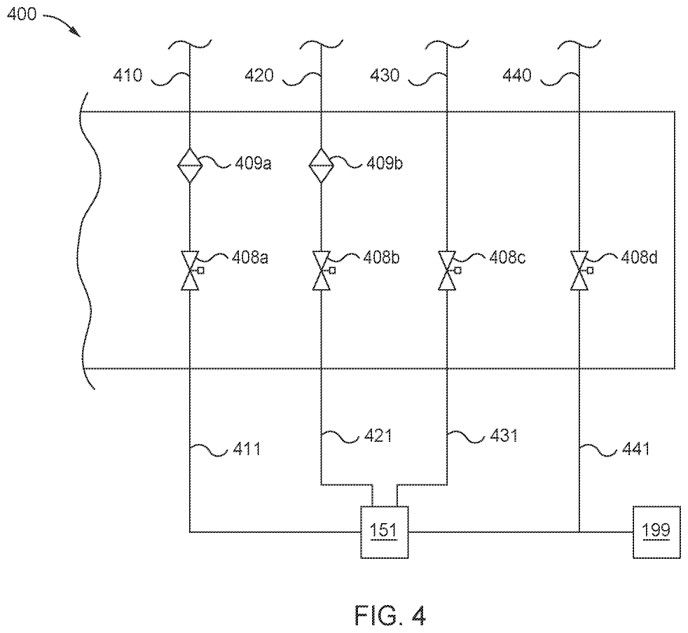

FIG. 4 is a schematic partial view of a process supply system 400, according to one implementation. The process supply system 400 is part of the gas supply system 190.

The process supply system 400 supplies one or more process gases (which can include one or more precursor gases) to the processing chamber 100. The process supply system 400 includes a plurality of inlet lines 411, 421, 431, 441 and a plurality of outlet lines 410, 420, 430, 440. In one or more embodiments, the one or more process gas sources 151 supply: chlorine (Cl) to a first inlet line 411 and a first outlet line 410, methylsilane (CH₃SiH₃) and argon (Ar) to a second inlet line 421 and a second outlet line 420, nitrogen (N₂) to a third inlet line 431 and a third outlet line 430, and hydrogen (H₂) to a fourth inlet line 441 and a fourth outlet line 440. In one or more embodiments, the hydrogen (H₂) is a carrier gas for the reactive gas(es) (such as methylsilane (CH₃SiH₃)) of the process gas(es).

In one or more embodiments, the one or more process gas sources 151 supply hydrogen (H₂) to the fourth inlet line 441 as a primary carrier gas, and the gas recycling system 199 supplies the filtered gas (having the purity content of hydrogen (H₂)) to the fourth inlet line 441 as a supplemental carrier gas. In one or more embodiments, the filtered gas is supplied without the primary carrier gas from the one or more process gas sources 151.

The plurality of outlet lines 410, 420, 430, 440 are fluidly connected to the process inlet passages 114 of the processing chamber 100 to supply the process gas(es) during a deposition operation. In one or more embodiments, the filtered gas is supplied to the fourth outlet line 440 but is not supplied to the first through third outlet lines 410, 420, 430.

A supply valve 408a, 408b, 408c, 408d, can correspond to each outlet line 410, 420, 430, 440. A filter 409a, 409b can correspond to each of the first outlet line 410 and the second outlet line 420. The present disclosure also contemplates that an MFC can correspond to each outlet line 410, 420, 430, 440.

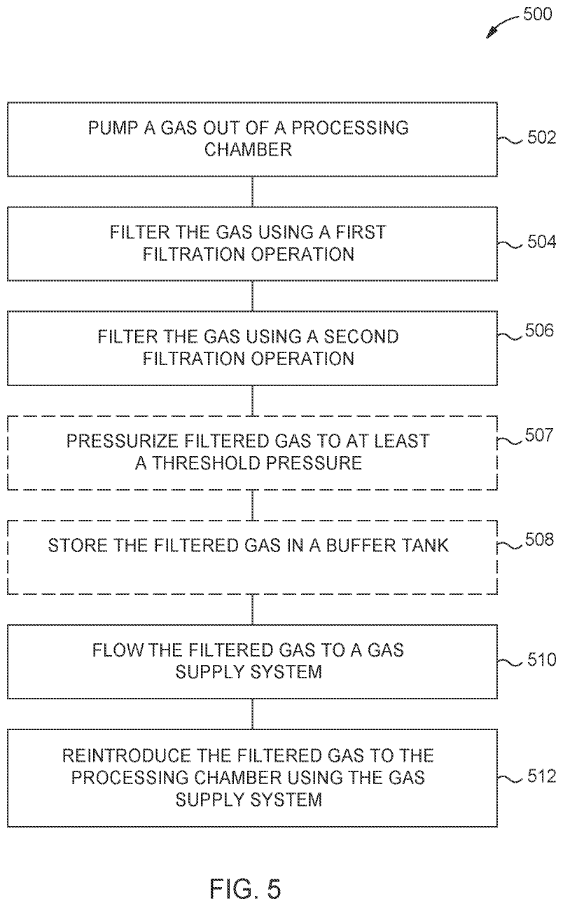

FIG. 5 is a schematic block diagram view of a method 500 of recycling gas in relation to semiconductor manufacturing, according to one implementation.

Operation 502 includes pumping a gas out of an internal volume of a processing chamber. The gas can be used gas that was used in a deposition operation of the processing chamber 100. The gas ca be pumped using the exhaust pump 157. The gas can be analyzed by the controller 120 to determine if the gas should be routed to the first filtration device 182 or the third filtration device 188. In one or more embodiments, if the gas is fit to be recycled the gas passes through the first flow divider 181 to the first filtration device 182. In one or more embodiments, if the gas is not fit to be recycled using the first and second filtration devices 182, 184 then the gas passes through the first flow divider 181 to the third filtration device 188.

Operation 504 includes filtering the gas using a first filtration operation (e.g., using the first filtration device 182).

Operation 506 includes filtering the gas using a second filtration operation (e.g., using the second filtration device 184) to generate a filtered gas having a purity content (e.g., the purity content discussed above). In one or more embodiments, the second filtration operation is substantially the same as the first filtration operation. In one or more embodiments, the second filtration operation is different than the first filtration operation. In one or more embodiments, the first filtration operation is a scrubbing operation and the second filtration operation is an electrochemical filtering operation.

Optional operation 507 includes pressurizing the filtered gas to at least a threshold pressure prior to the reintroducing of the filtered gas to the processing chamber.

Optional operation 508 includes storing (at least temporarily) the filtered gas in a buffer tank prior to reintroducing the filtered gas to the processing chamber.

Operation 510 includes flowing the filtered gas to a gas supply system (e.g., from the second flow divider 183 or the buffer tank). The filtered gas is directed to one or more of the purge supply system 200, the cleaning supply system 300, and/or the process supply system 400 using the controller 120.

Operation 512 includes reintroducing the filtered gas to the processing chamber using the gas supply system. The filtered gas is supplied back to the processing chamber as recycled gas, for use again in the processing chamber. The filtered gas can be used as at least part of purge gas (e.g, through the purge supply system 200), cleaning gas (e.g., as high flow HCL cleaning gas through the cleaning supply system 300), and/or process gas (e.g., as a carrier gas for precursor gas(es) through the process supply system 400).

Benefits of the present disclosure include reusing gases that go through a processing chamber unreacted; reducing waste of gases in semiconductor manufacturing; reduced emissions and carbon footprints; reduced gas consumption and energy consumption; and reduced operating costs (such as materials costs, delivery costs, and/or power costs). As an example, gases that would otherwise be flared are filtered (e.g., cleaned) and reused in the processing chamber to reduce flaring energy expenditures and save energy and money. The recycled gases (depending, e.g., on purity) can be used for a multitude of tasks, such as purging, cleaning, and/or processing (e.g., as carrier gases). Using gas recycling for the purity content described, non-reacted gases like hydrogen can be reused for purging, cleaning, and/or processing to facilitate lowering the amount of hydrogen gas needed to run the processing chamber over time. In one or more embodiments, 75% or more (such as 75-85% or more) of hydrogen used in a processing chamber is recovered for re-use.

It is contemplated that one or more aspects disclosed herein may be combined. As an example, one or more aspects, features, components, operations and/or properties of the processing chamber 100, the controller 120, the gas supply system 190, the gas recycling system 199, the flow dividers 181, 183, the filtration devices 182, 184, 188, the exhaust pump 157, the buffer tank 186, the purge supply system 200, the cleaning supply system 300, the process supply system 400, and/or the method 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A gas recycling system for connection to a processing chamber, comprising:
a pump configured to fluidly connect to one or more outlet passages of the processing chamber to exhaust a gas from the processing chamber;
one or more filtration devices in fluid communication with the pump such that the gas flows from the pump to the one or more filtration devices, the one or more filtration devices configured to remove one or more impurities from the gas to generate a filtered gas that has a purity content of 99.9% or higher; and
a gas supply system in fluid communication with the one or more filtration devices such that the filtered gas flows from the one or more filtration devices to the gas supply system, the gas supply system configured to fluidly connect to one or more inlet passages of the processing chamber.

2. The gas recycling system of claim 1, wherein the one or more filtration devices comprise:
a first filtration device; and
a second filtration device in fluid communication between the first filtration device and the gas supply system such that the gas flows from the first filtration device to the second filtration device.

3. The gas recycling system of claim 2, further comprising:
a third filtration device in fluid communication between the pump and a bypass line that bypasses the one or more filtration devices; and
a controller comprising instructions that, when executed, cause a plurality of operations to be conducted, the plurality of operations comprising:
identifying a first portion and a second portion of the gas,
directing the first portion of the gas to the first filtration device, and
directing the second portion of the gas to the third filtration device.

4. The gas recycling system of claim 2, wherein the first filtration device is a scrubber and the second filtration device is an electrochemical filter.

5. The gas recycling system of claim 1, wherein the gas supply system comprises:
a purge supply system in fluid communication with one or more purge gas sources;
a process supply system in fluid communication with one or more reactive gas sources and one or more carrier gas sources; and
a cleaning supply system in fluid communication with one or more cleaning gas sources.

6. The gas recycling system of claim 5, wherein the filtered gas flows into one or more of the purge supply system, the process supply system, or the cleaning supply system.

7. The gas recycling system of claim 1, further comprising:
a buffer tank in fluid communication between the one or more filtration devices and the gas supply system,
a compressor in fluid communication between the one or more filtration devices and the buffer tank, wherein the compressor is configured to pressurize the filtered gas.

8. A system for substrate processing, comprising:
a processing chamber comprising:
a chamber body at least partially defining an internal volume,
a plurality of inlet passages,
one or more outlet passages,
a substrate support disposed in the internal volume,
one or more heat sources configured to heat the internal volume;
a gas supply system in fluid communication with the plurality of inlet passages to supply a gas to the internal volume of the processing chamber; and
a gas recycling system in fluid communication between the one or more outlet passages and the gas supply system, the gas recycling system comprising:
a pump in fluid communication with the one or more outlet passages to remove the gas from the internal volume of the processing chamber, and
one or more filtration devices in fluid communication between the pump and the gas supply system such that the gas flows from the pump to the one or more filtration devices, the one or more filtration devices configured to remove one or more impurities from the gas to generate a filtered gas that has a purity content of 99.9% or higher, the one or more filtration devices in fluid communication with the gas supply system such that the filtered gas flows from the one or more filtration devices to the gas supply system.

9. The gas recycling system of claim 8, wherein the one or more filtration devices comprises a first filtration device that is a scrubber, and the purity content is a concentration of hydrogen (H₂) by atomic percentage.

10. The gas recycling system of claim 8, wherein the one or more filtration devices further comprises a second filtration device that is an electrochemical filter.

11. The system of claim 8, wherein the gas supply system comprises:
a purge supply system comprising one or more first mass flow controllers (MFCs) and one or more purge header lines in fluid communication with one or more purge gas sources;
a process supply system in fluid communication with one or more reactive gas sources and one or more carrier gas sources; and
a cleaning supply system comprising one or more second mass flow controllers (MFCs) and one or more cleaning header lines in fluid communication with one or more cleaning gas sources.

12. The system of claim 11, wherein the filtered gas flows from the one or more filtration devices into the one or more purge header lines of the purge supply system on an upstream side of the one or more first MFCs.

13. The gas recycling system of claim 11, wherein the filtered gas flows from the one or more filtration devices into the one or more cleaning header lines of the cleaning supply system on an upstream side of the one or more second MFCs.

14. The gas recycling system of claim 11, wherein the filtered gas flows from the one or more filtration devices into the process supply system, and the filtered gas is a carrier gas.

15. A method of recycling gas in relation to semiconductor manufacturing, comprising:
pumping a gas out of an internal volume of a processing chamber;
filtering the gas using a first filtration operation;
filtering the gas using a second filtration operation to generate a filtered gas that has a purity content of 99.9% or higher;
flowing the filtered gas to a gas supply system; and
reintroducing the filtered gas to the processing chamber using the gas supply system.

16. The method of claim 15, wherein the flowing of the filtered gas to the gas supply system comprises:
supplying the filtered gas to a purge supply system of the gas supply system as a supplemental purge gas, in addition to a primary purge gas supplied to the purge supply system.

17. The method of claim 15, wherein the flowing of the filtered gas to the gas supply system comprises:
supplying the filtered gas to a process supply system of the gas supply system as a carrier gas while supplying a reactive gas to the process supply system.

18. The method of claim 15, wherein the flowing of the filtered gas to the gas supply system comprises:
supplying the filtered gas to a cleaning supply system of the gas supply system as a supplemental cleaning gas, in addition to a primary cleaning gas supplied to the cleaning supply system.

19. The method of claim 15, further comprising storing the filtered gas in a buffer tank prior to the reintroducing of the filtered gas to the processing chamber.

20. The method of claim 15, further comprising pressurizing the filtered gas to at least a threshold pressure prior to the reintroducing of the filtered gas to the processing chamber.
